(19) United States
(12) Patent Application Publication
(10) Pub. No.: US 2017/0110589 A1
(43) Pub. Date: Apr. 20, 2017

(54) SEMICONDUCTOR STRUCTURE

(71) Applicant: UNITED MICROELECTRONICS CORP., HSINCHU (TW)

(72) Inventors: Ching-Chung Yang, Hsinchu City (TW); Shih-Yin Hsiao, Chiayi County (TW)

(21) Appl. No.: 14/882,663

(22) Filed: Oct. 14, 2015

(51) Int. Cl. H01L 29/786; H01L 29/06; H01L 29/423

(52) U.S. Cl. CPC H01L 29/78609; H01L 29/78696; H01L 29/42384; H01L 29/0653

(57) ABSTRACT

A semiconductor structure is provided. The semiconductor structure includes a substrate, a diffusion region, a first oxide layer, a second oxide layer and a polysilicon layer. The diffusion region is formed in the substrate and has a source and a drain extended along a first direction. The first oxide layer is formed on the substrate. The second oxide layer is formed in the substrate and adjacent to the drain. The polysilicon layer is formed on the substrate and has a first region, a second region, and a third region. The second region is formed on an edge of the second oxide layer and between the first region and the third region. A width of the second region is less than a width of the first region and a width of the third region along the first direction.

### BACKGROUND

Technical Field

The disclosure relates in general to a semiconductor structure, and more particularly to a semiconductor structure for improving off-state hot carrier injection (HCI).

Description of the Related Art

In the past few years, accompanying the great expansion of electronic communication products, for example mobile phones, drivers of liquid crystal displays (LCDs) have come to be especially important. With a trend toward scaling down the size of the semiconductor components, the line width of interconnections has continuously shrunk. In general, high-voltage metal oxide semiconductor (HVMOS) devices have been widely applied in a variety of semiconductor components. However, the off-state hot carrier injection (HCI) in the traditional semiconductor structure is worse, so that it is important to form a new structure which can improve the off-state HCI and results in less influence on device performances.

### SUMMARY

The disclosure is directed to a semiconductor structure. By the step of cutting a portion of the polysilicon layer at the edge of the polysilicon, it could be easy to improve the off-state hot carrier injection and results in less influence on device performances.

According to one embodiment, a semiconductor structure is provided. The semiconductor structure includes a substrate, a diffusion region, a first oxide layer, a second oxide layer and a polysilicon layer. The diffusion region is formed in the substrate and has a source and a drain extended along a first direction. The first oxide layer is formed on the substrate. The second oxide layer is formed in the substrate and adjacent to the drain. The polysilicon layer is formed on the substrate and has a first region, a second region, and a third region. The second region is formed on an edge of the second oxide layer and between the first region and the third region. A width of the second region is less than a width of the first region and a width of the third region along the first direction.

### BRIEF DESCRIPTION OF THE DRAWINGS

FIG. 1A illustrates a top view of the semiconductor structure according to an embodiment of the disclosure.

FIG. 1B illustrates a cross-section view of the semiconductor structure along line A-A′ in FIG. 1A.

FIG. 2 shows the results of the off-state stress test.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

The embodiments are described in details with reference to the accompanying drawings. The identical elements of the embodiments are designated with the same reference numerals. Also, it is important to point out that the illustrations may not be necessarily drawn to scale, and that there may be other embodiments of the present disclosure which are not specifically illustrated. Thus, the specification and the drawings are to be regard as an illustrative sense rather than a restrictive sense.

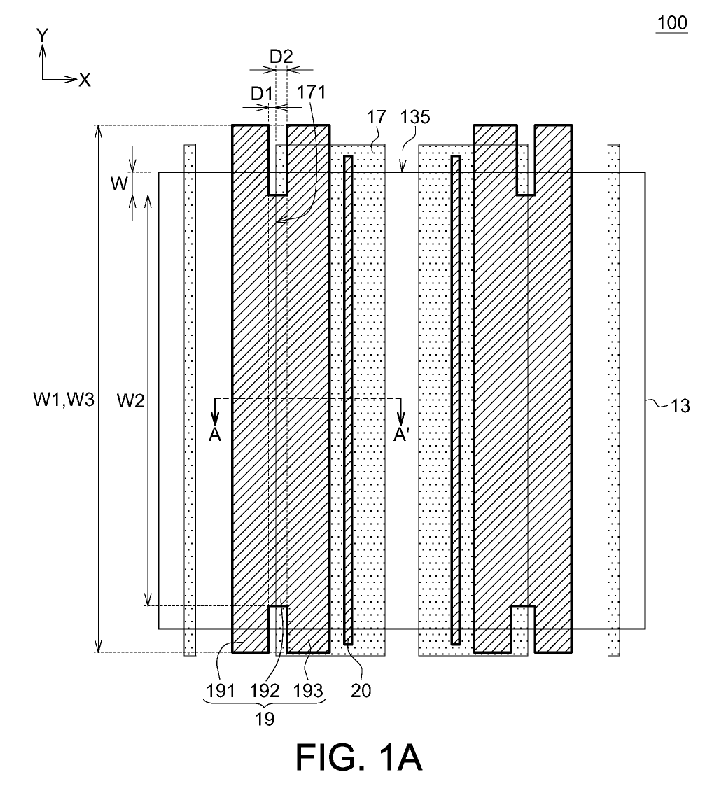

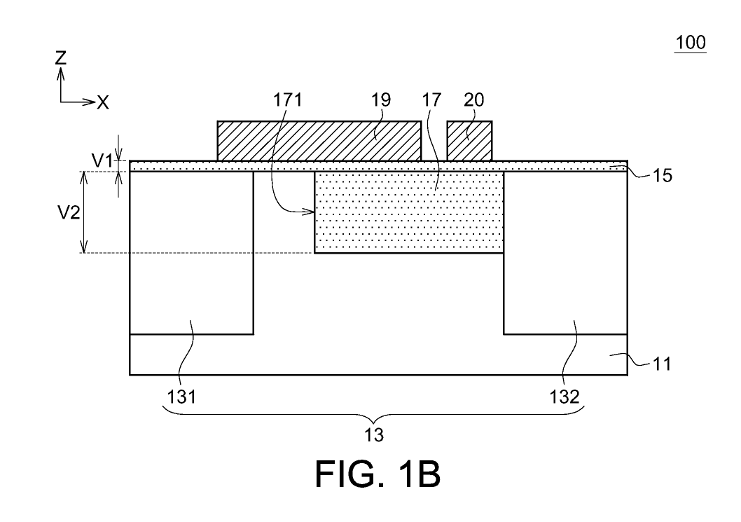

FIG. 1A illustrates a top view of the semiconductor structure 100 according to an embodiment of the disclosure. FIG. 1B illustrates a cross-section view of the semiconductor structure 100 along line A-A′ in FIG. 1A. It should be noted that some elements are omitted in FIG. 1A to show the semiconductor structure 100 more clearly.

As shown in FIG. 1A and FIG. 1B, the semiconductor structure 100 includes a substrate 11, a diffusion region 13, a first oxide layer 15, a second oxide layer 17 and a polysilicon layer 19.

In one embodiment, the diffusion region 13 is formed in the substrate 11 and may have a source 131 and a drain 132 extended along a first direction. Here, the first direction may be parallel with Y-direction in FIG. 1A. The first oxide layer 15 is formed on the substrate 11, and the second oxide layer 17 formed in the substrate 11 and adjacent to the drain 132. The polysilicon layer 19 is formed on the substrate 11.

It would be shown from the analysis of the off-state stress electrical field by the technology computer aided design (TOAD) that the location of max electrical field may be at the interface between the first oxide layer 15 and the second oxide layer 17 and at the width edge of the polysilicon layer 19.

In one embodiment, the width edge of the polysilicon layer 19 may be perpendicular to the first direction (Y-direction), for example, parallel with X-direction. The first oxide layer 15 may be an I/O oxide layer, and the second oxide layer 17 may be a high-voltage (HV) oxide layer. Besides, the interface between the first oxide layer 15 and the second oxide layer 17 may be at the edge 171 of the second oxide layer 17 parallel with the first direction (Y-direction).

Therefore, the step of cutting a portion of the polysilicon layer 19 at the width edge of the polysilicon layer 19 may be implemented to form the semiconductor structure 100 in the embodiment of the disclosure, such that the polysilicon layer 19 may be divided to have a first region 191, a second region 192 and a third region 193.

In this embodiment, the second region 192 of the polysilicon layer 19 is formed on the edge 171 of the second oxide layer 17 and formed between the first region 191 and the third region 193 of the polysilicon layer 19 as shown in FIG. 1A.

Further, a width W2 of the second region 192 is less than a width W1 of the first region 191 and a width W3 of the third region 193 along the first direction (Y-direction). In this embodiment, the width W1 of the first region 191 and the width W3 of the third region 193 may be the same, but the disclosure is not limited thereto.

As shown in FIG. 1B, a depth V1 of the first oxide layer 15 is less than a depth V2 of the second oxide layer 17 (along Z-direction). For example, the depth V1 of the first oxide layer 15 may be between 0.005 and 0.011 μm, while the depth V2 of the second oxide layer 17 may be between 0.085 and 0.1 μm.

As shown in FIG. 1A, a distance D1 between the edge 171 of the second oxide layer 17 and the first region 191 along a second direction (X-direction) perpendicular to the first direction (Y-direction) may be between 0.15 and 0.2 μm, and a distance D2 between the edge 171 of the second oxide layer 17 and the third region 193 along the second direction (X-direction) may be between 0.15 and 0.25 μm.

Further, a distance W between the second region 192 of the polysilicon layer 19 and an edge 135 of the diffusion region 13 along the first direction (Y-direction) may be between 0.3 and 0.5 μm.

In some embodiments, the semiconductor structure 100 may further include at least one shallow trench isolation (STI)(not shown) formed in the substrate 11 and extended along the second direction (X-direction) to isolate the source 131 and the drain 132 of the diffusion region 13. Besides, the semiconductor structure 100 may also include a dummy polysilicon layer 20 formed on the second oxide layer 17 as shown in FIG. 1A and FIG. 1B.

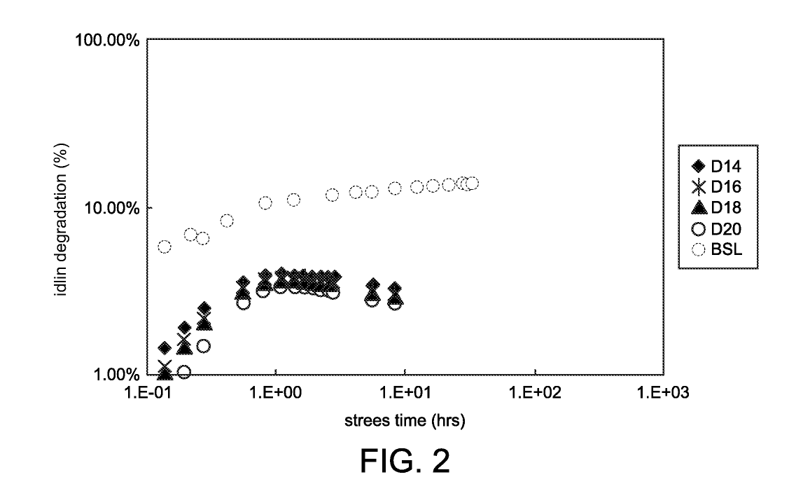

FIG. 2 shows the results of the off-state stress test. In FIG. 2, curve BSL represents the semiconductor structure without implementing the cutting process (that is, the polysilicon layer of the semiconductor structure may not be divided into several regions having different widths), and curves D14, D16, D18, D20 represent the semiconductor structure 100 which are conducted by different positions of pins of the semiconductor structure 100 in the embodiment of the disclosure.

As shown in FIG. 2, no matter the semiconductor structure 100 in the embodiment of the disclosure is conducted by which position of pins, the off-state hot carrier injection in the semiconductor structure 100 of the disclosure may be improved compared with the semiconductor structure without implementing the cutting process (BSL).

TABLE 1 shows the WAT data corresponding to curve BSL, D14, D16, D18 and D20.

TABLE 1

| | BSL | D14 | D16 | D18 | D20 |
|---|---|---|---|---|---|
| Vₜₒ | 1.189 | 1.184 | 1.189 | 13190 | 1.192 |
| diff. | | −0.004 | 0.000 | 0.001 | 0.003 |
| Idlin | 2.10E−04 | 2.06E−04 | 2.07E−04 | 2.06E−04 | 2.06E−04 |
| diff. | | −1.5% | −1.4% | −1.6% | −1.7% |
| BV | 53 | 53 | 53 | 53 | 53 |
| diff. | | 0 | 0 | 0 | 0 |

As the results shown in TABLE 1, there is little impact on device performances in the semiconductor structure 100 of the disclosure (compared with the semiconductor structure without implementing the cutting process).

As described above, the semiconductor structure in the embodiment of the disclosure does not need extra mask, but only need to modify the layout of the structure. Further, the semiconductor structure in the embodiment of the disclosure can improve the off-state HCI and results in less influence on device performances.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A semiconductor structure, comprising:
a substrate;
a diffusion region formed in the substrate and having a source and a drain extended along a first direction;
a first oxide layer formed on the substrate;
a second oxide layer formed in the substrate and adjacent to the drain; and
a polysilicon layer formed on the substrate and having a first region, a second region, and a third region;
wherein the second region is formed on an edge of the second oxide layer and between the first region and the third region, the second region is recessed from an outer edge of an outer sidewall of the polysilicon layer parallel to a second direction from the source to the drain, the outer sidewall is between an upper surface and a lower surface of the polysilicon layer, and a width of the second region is less than a width of the first region and a width of the third region along the first direction.

2. The semiconductor structure according to claim 1, wherein a thickness of the first oxide layer is less than a thickness of the second oxide layer.

3. The semiconductor structure according to claim 2, wherein the thickness of the first oxide layer is between 0.005 and 0.011 μm.

4. The semiconductor structure according to claim 2, wherein the thickness of the second oxide layer is between 0.085 and 0.1 μm.

5. The semiconductor structure according to claim 1, wherein a distance between the edge of the second oxide layer and the first region along the second direction perpendicular to the first direction is between 0.15 and 0.2 μm.

6. The semiconductor structure according to claim 5, wherein a distance between the edge of the second oxide layer and the third region along the second direction is between 0.15 and 0.25 μm.

7. The semiconductor structure according to claim 1, wherein a distance between the second region of the polysilicon layer and an edge of the diffusion region along the first direction is between 0.3 and 0.5 μm.

8. The semiconductor structure according to claim 1, wherein the width of the first region and the width of the third region are the same.

9. The semiconductor structure according to claim 1, further comprising at least one shallow trench isolation formed in the substrate and extended along the second direction perpendicular to the first direction.
